(19) United States
(12) Patent Application Publication
(10) Pub. No.: US 2025/0359143 A1
(43) Pub. Date: Nov. 20, 2025

(54) SEMICONDUCTOR DEVICE WITH CURRENT PROPAGATION REGION AND METHOD OF MANUFACTURING

(71) Applicant: Infineon Technologies AG, Neubiberg (DE)

(72) Inventors: Caspar LEENDERTZ, München (DE); Andreas VÖRCKEL, Finkenstein (AT); Kristijan Luka MLETSCHNIG, Klagenfurt (AT); Frank HILLE, München (DE)

(21) Appl. No.: 19/208,117

(22) Filed: May 14, 2025

(30) Foreign Application Priority Data
May 15, 2024 (DE) 102024204506.3

(51) Int. Cl. H10D 30/66; H10D 30/01; H10D 62/10; H10D 62/40; H10D 62/60; H10D 62/832

(52) U.S. Cl. CPC H10D 30/668; H10D 30/0297; H10D 62/102; H10D 62/124; H10D 62/40; H10D 62/60; H10D 62/8325

(57) ABSTRACT

A semiconductor device includes a foundation layer and a transistor layer. The foundation layer is based on single-crystalline silicon carbide and includes a current propagation region of a first conductivity type and a non-depletable shielding structure of a second conductivity type. The transistor layer is based on epitaxially grown single-crystalline silicon carbide and includes a transistor cell (TC) configured to control a current through the current propagation region. The transistor layer is formed on the foundation layer after formation of the shielding structure in the foundation layer such that an epitaxial interface forms between the transistor foundation layer and the layer. The current propagation region extends from the epitaxial interface between neighboring partial regions of the shielding structure. Along a vertical line orthogonal to the epitaxial interface and through a pn junction between the shielding structure and a region of the first conductivity type in the transistor layer, a net dopant concentration changes by at least 1e17 1/cm³ per 0.1 μm at the position of the pn junction.

### RELATED APPLICATION

This application claims priority to German Patent Application No. 102024204506.3, filed on May 15, 2024, entitled “SEMICONDUCTOR DEVICE WITH CURRENT PROPAGATION REGION AND METHOD OF MANUFACTURING”, which is incorporated by reference herein in its entirety.

### TECHNICAL FIELD

The present disclosure relates to a semiconductor device based on silicon carbide and with a current propagation region. The present disclosure further relates to a method of manufacturing a semiconductor device based on silicon carbide.

### BACKGROUND

In silicon carbide MOSFETs with planar gate, the gate dielectric and the gate conductor are formed on the first main surface. In silicon carbide trench MOSFETs, the gate dielectric and the gate conductor are formed in gate trenches extending from a first main surface at a front side of a silicon carbide portion into the silicon carbide portion. In both types of silicon carbide MOSFETS (SiC-MOSFETs), the gate dielectric separates the gate conductor from weakly doped p conductive body regions which are formed in the silicon carbide portion. In the on-state of the SiC-MOSFET, an electron channel forms in a channel portion of the body region along the gate dielectric. An n conductive drift layer is formed in a part of the silicon carbide portion between the body region and a second main surface of the silicon carbide portion opposite to the first main surface. Heavily doped p conductive shielding regions formed between the weakly doped p conductive body region and the drift layer shield the body regions with the channel portion against the potential of the drift layer and reduce the electric field in the body regions The shielding regions for trench SiC-MOSFETs can be formed by implanting acceptor ions through a bottom of the gate trenches before depositing the gate conductor material in the gate trenches. For SiC-MOSFETs with planar gates, the acceptor ions are implanted through the first main surface, wherein high implantation energies are used to reach an implant depth deeper than the weakly doped p conductive body region.

There is a constant need to improve the on-state resistance of SiC-MOSFETs, e.g. SiC-MOSFETs with trench gates and SiC-MOSFETS with planar gates.

### SUMMARY

A semiconductor device in accordance with the present disclosure includes a foundation layer and a transistor layer. The foundation layer is based on single-crystalline silicon carbide and includes a current propagation region of a first conductivity type and a non-depletable shielding structure of a second conductivity type. The transistor layer is based on epitaxially grown single-crystalline silicon carbide and includes a transistor cell that controls a current through the current propagation region. The transistor layer is formed on the foundation layer after formation of the shielding structure in the foundation layer, wherein an epitaxial interface forms between the foundation layer and the transistor layer. The current propagation region extends from the epitaxial interface between neighboring partial regions of the shielding structure. Along a vertical line orthogonal to the epitaxial interface and through a pn junction between the shielding structure and a region of the first conductivity type in the transistor layer, a net dopant concentration changes at the position of the pn junction by at least 1e17 1/cm³ per 0.1 μm.

Since the acceptor ions for the shielding structure can be implanted before the transistor layer is formed, the acceptor ions do not pass through the transistor layer. Lateral straggle can be reduced. Formation of implantation tails in the transistor layer can be prevented or at least mitigated. The absence of implantation tails can facilitate the formation of narrow current paths through the shielding structure. Since the energy required to implant the shielding structure into the foundation layer can be comparatively low, the implantation mask can be made significantly thinner than if the acceptor ions are implanted through the transistor layer. As a result, the lateral dimension of the shielding structure and the lateral transitions between the shielding structure and the current paths can be defined more precisely. The semiconductor device can combine a low on-state resistance RDSon with highly efficient shielding for the body region.

The disclosure relates to semiconductor devices based on silicon carbide and having transistor cells. Specific examples for such a semiconductor device include a n-channel SiC-MOSFET with planar gate or a n-channel SiC-TMOSFET. Nevertheless, the disclosure is also applicable to p-channel SiC-MOSFETS.

Those skilled in the art will recognize additional features and advantages by reading the following detailed description and viewing the accompanying drawings.

### BRIEF DESCRIPTION OF THE DRAWINGS

The accompanying drawings are provided for further understanding of the embodiments and form an integral part of this description. The drawings illustrate embodiments of a semiconductor device and a method of manufacturing a semiconductor device and, together with the description, explain the principles underlying the embodiments. Further embodiments are described in the following detailed description and in the claims. Features of the various embodiments may be combined with each other.

FIG. 1A is a schematic vertical cross-sectional view of a portion of a semiconductor device with a current propagation region laterally confined by regions of a non-depletable shielding structure in accordance with an embodiment.

FIG. 1B is a schematic diagram illustrating the dopant concentration along a vertical line B-B in FIG. 1A in accordance with an embodiment.

FIG. 1C is a schematic diagram illustrating the dopant concentration along a horizontal line C-C in FIG. 1A in accordance with an embodiment.

FIG. 2 is a schematic vertical cross-sectional view of a portion of a semiconductor device with a current propagation region laterally confined by regions of a non-depletable shielding structure in accordance with an embodiment relating to transistor cells with planar gate electrode.

FIG. 3 is a schematic vertical cross-sectional view of a portion of a semiconductor device with a current propagation region laterally confined by regions of a non-depletable shielding structure in accordance with an embodiment relating to trench gate structures in direct contact with the shielding structure.

FIG. 4 is a schematic vertical cross-sectional view of a portion of a semiconductor device with a current propagation region laterally confined by regions of a non-depletable shielding structure in accordance with an embodiment relating to trench gate structures spaced apart from the shielding structure.

FIG. 5 is a schematic diagram illustrating the dopant concentration gradient along a vertical line through the epitaxial interface between a current propagation region and a current collecting region in accordance with an embodiment.

FIG. 6A is a schematic diagram illustrating the dopant concentration gradient along a vertical line through the epitaxial interface between a shielding structure and a connection region in accordance with an embodiment.

FIG. 6B is a schematic diagram illustrating the dopant concentration gradient along a vertical line through the epitaxial interface between a shielding structure and a current collecting region of a transistor cell with trench gate structure in accordance with an embodiment.

FIG. 7 and FIG. 8 are schematic vertical cross-sectional views of a portion of a semiconductor device in accordance with an embodiment relating to transistor cells with planar gate electrodes.

FIG. 9 is schematic vertical cross-sectional view of a portion of a semiconductor device in accordance with an embodiment relating to transistor cells with trench gate electrodes and one-sided transistor channel.

FIG. 10 is schematic vertical cross-sectional view of a portion of a semiconductor device in accordance with an embodiment relating to transistor cells with trench gate electrodes and two-sided transistor channel.

FIG. 11 is schematic vertical cross-sectional view of a portion of a semiconductor device in accordance with an embodiment relating to transistor cells with metal contact plugs extending from a top surface into the transistor layer 100.

FIG. 12 is schematic horizontal cross-sectional view of a portion of a semiconductor device having stripe-shaped trench gate structures in accordance with an embodiment with n conductive source regions and p conductive contact regions alternating along a horizontal longitudinal axis of the trench gate structures.

FIG. 13A and FIG. 13B are schematic vertical cross-sectional views along lines I-I and II-II of FIG. 12 in accordance with an embodiment relating to wide n conductive channel portions laterally confined by the shielding structure.

FIG. 14A and FIG. 14B are schematic vertical cross-sectional views along lines I-I and II-II of FIG. 12 in accordance with an embodiment relating to narrow n conductive channel portions laterally confined by the shielding structure.

FIG. 15A and FIG. 15B are schematic vertical cross-sectional views along lines I-I and II-II of FIG. 12 in accordance with an embodiment relating to narrow n conductive channel portions and trench gate structures not reaching the foundation layer.

FIG. 16A and FIG. 16B are schematic vertical cross-sectional views along lines I-I and II-II of FIG. 12 in accordance with an embodiment relating to p conductive narrow auxiliary regions vertically separating the trench gate structures and the shielding structure, wherein pillars of a compensation structure run parallel to stripe-shaped trench gate structures.

FIG. 17A, FIG. 17B, FIG. 17C are schematic vertical cross-sectional views along lines I-I, II-II, and IV-IV of FIG. 12 in accordance with an embodiment relating to p conductive narrow auxiliary regions vertically separating the trench gate structures and a grid-shaped shielding structure, wherein pillars of a compensation structure run orthogonal to stripe-shaped trench gate structures.

FIG. 17D is a schematic vertical cross-sectional view along a line parallel to the line I-I of FIG. 12 in accordance with an embodiment, wherein pillars of a compensation structure run orthogonal to stripe-shaped trench gate structures and stripe-shaped partial regions of the shielding structure run parallel to stripe-shaped trench gate structures.

FIG. 18A and FIG. 18B are schematic vertical cross-sectional views along lines I-I and II-II of FIG. 12 in accordance with an embodiment, wherein pillars of a compensation structure run orthogonal to stripe-shaped trench gate structures and the shielding structure includes laterally separated shielding islands.

FIG. 19A, FIG. 19B and FIG. 19C are schematic vertical cross-sectional views along lines I-I, II-II and III-III of FIG. 12 in accordance with an embodiment, wherein pillars of a compensation structure and stripe-shaped partial regions of the shielding structure run orthogonal stripe-shaped to trench gate structures.

FIG. 20 is a schematic vertical cross-sectional view of a portion of a semiconductor device in accordance with an embodiment relating to a current propagation region having a central channel portion and heavily doped sidewall portions between the central channel portion and the shielding structure.

FIG. 21A to FIG. 21B are schematic vertical cross-sectional views of a portion of a semiconductor device illustrating a method of manufacturing a semiconductor device in accordance with an embodiment, before and after the formation of a transistor layer on a foundation layer in which a shielding structure is formed.

FIG. 22A to FIG. 22D are schematic vertical cross-sectional views of a portion of a semiconductor device illustrating a method of manufacturing a semiconductor device with a compensation structure in accordance with another embodiment.

FIG. 23A to FIG. 23D are schematic vertical cross-sectional views of a portion of a semiconductor device illustrating a method of manufacturing a semiconductor device in accordance with an embodiment relating to a current propagation region having a central channel portion and heavily doped sidewall portions between the central channel portion and the shielding structure.

### DETAILED DESCRIPTION

In the following detailed description, reference is made to the accompanying drawings which form a part of this document and in which certain embodiments of a semiconductor device and a method of manufacturing a semiconductor shown device are as illustrations. Structural or logical changes may be made to the illustrated embodiments without departing from the scope of the present disclosure. For example, features shown or described for one embodiment may be used on or in conjunction with other embodiments, resulting in another embodiment. The present disclosure is intended to include such modifications and variations. The embodiments are described in a manner that should not be construed as limiting the scope of the appended claims. The drawings are not to scale and are for illustrative purposes only. Corresponding elements are designated by the same reference numerals in the various drawings, unless otherwise indicated.

The terms “having”, “containing”, “including”, “comprising” and the like are open-ended, and the terms indicate the presence of certain structures, elements or features but do not preclude the presence of additional elements or features. The articles “a”, “an” and “the” include both the plural and singular, unless the context clearly indicates otherwise.

The terms “signal-connected” and “electrically connected” may include a permanent low-resistive ohmic connection between electrically connected elements, for example a direct contact between the concerned elements or a low-resistive connection via a metal and/or heavily doped semiconductor material, but do not preclude the presence of further passive and/or active elements in the signal path between the “signal-connected” or “electrically connected” elements. For example, the further elements may include resistors, resistive conductor lines, capacitors and/or inductors, transistors, semiconductor diodes, Schottky diodes, transformers, opto-couplers and other.

The term “directly electrically connected” may describe a permanent low-resistive ohmic connection between electrically connected elements, for example a direct contact between the concerned elements or a low-resistive connection via a metal and/or heavily doped semiconductor material.

The term “power semiconductor device” refers to semiconductor devices with a high voltage blocking capability of at least 30 V, for example 48 V, 100 V, 600 V, 1.6 kV, 3.3 kV or more and with a nominal on-state current or forward current of at least 200 mA, for example 1 A, 10 A or more.

A safe operating area (SOA) of a semiconductor device is defined as the voltage and current conditions over which the semiconductor device can be expected to operate without self-damage.

An ohmic contact describes a non-rectifying electrical junction between two conductors, e.g., between a semiconductor material and a metal. The ohmic contact has a linear or approximately linear current-voltage (I-V) curve in the first and third quadrant of the I-V diagram as with Ohm's law.

Ranges given for physical dimensions include the boundary values. For example, a range for a parameter y from a to b reads as a≤y≤b. The same holds for ranges with one boundary value like “at most” and “at least”.

The term “on” is not to be construed as meaning only “directly on”. Rather, if one element is positioned “on” another element (e.g., a layer is “on” another layer or “on” a substrate), a further component (e.g., a further layer) may be positioned between the two elements (e.g., a further layer may be positioned between a layer and a substrate if the layer is “on” said substrate).

Two adjoining doping regions in a semiconductor layer form a semiconductor junction. Two adjoining doping regions of the same conductivity type and with different dopant concentrations form a unipolar junction, e.g., an n/n+ or p/p+ junction along a boundary surface between the two doping regions. At the unipolar junction a dopant concentration profile orthogonal to the unipolar junction may show a step or a turning point, at which the dopant concentration profile changes from being concave to convex, or vice versa. Two adjoining doping regions of complementary conductivity form a pn junction.

The Figures illustrate relative doping concentrations by indicating “−” or “+” next to the doping type “n” or “p”. For example, “n−” means a doping concentration which is lower than the doping concentration of an “n”-doping region while an “n+”-doping region has a higher doping concentration than an “n”-doping region. Doping regions of the same relative doping concentration do not necessarily have the same absolute doping concentration. For example, two different “n”-doping regions may have the same or different absolute doping concentrations.

The shielding regions confine the transistor on-state current in the lateral directions and increase the on-state resistance RDSon of SiC-MOSFETs with planar gates and with trench gates. The high energy implant through the first main surface leads to a large lateral straggle that blurs the lateral edges of the shielding regions. The high energy implant also requires a thick implant mask to prevent the acceptor ions from reaching the current paths between the shielding regions. With increasing thickness, undesired side effects of the implant mask become more pronounced. A slight tilt of mask edges leads to lateral straggle and only partial blocking of the ions. The only partial blocking results in implantation tails (“ducktails”) reaching to the first main surface. The implantation tails can increase the channel resistance and/or change the threshold voltage of the SiC-MOSFET. Negative side effects of the high-energy implantations can be mitigated by increasing the lateral distance between neighboring gate trenches, which in turn lowers the area efficiency.

The present disclosure relates to a semiconductor device having a foundation layer and a transistor layer. The foundation layer is based on single-crystalline silicon carbide and includes a current propagation region of a first conductivity type and a non-depletable shielding structure of a second conductivity type. The transistor layer is based on epitaxially grown single-crystalline silicon carbide and includes a transistor cell configured to control a current through the current propagation region. The transistor layer is formed on the foundation layer after formation of the shielding structure in the foundation layer such that an epitaxial interface forms between the foundation layer and the transistor layer. The current propagation region extends from the epitaxial interface between neighboring partial regions of the shielding structure. Along a vertical line orthogonal to the epitaxial interface and through a pn junction between the shielding structure and a region of the first conductivity type in the transistor layer, a net dopant concentration may change at the position of the pn junction by at least 1e17 1/cm³ per 0.1 μm, e.g., by at least 2e17 1/cm³ per 0.1 μm.

According to an example, the first conductivity type is n conductivity and the second conductivity type is p conductivity. According to another example, the first conductivity type is p conductivity and the second conductivity type is n conductivity.

The foundation layer may have two rectangular main surfaces extending in two essentially parallel horizontal planes. A distance between a first main surface at a front side (foundation layer surface) and a second main surface opposite to the first main surface defines a thickness of the foundation layer in a vertical direction orthogonal to the horizontal planes. Current propagation regions and the shielding structure may extend from the epitaxial interface into the foundation layer.

The transistor layer may be formed directly on the foundation layer surface. The transistor layer may be formed by epitaxial growth of crystalline silicon carbide after formation of the shielding structure.

The transistor layer may include further components to provide the functionality of a plurality of transistor cells. For example, the transistor layer may include structures made of materials other than monocrystalline silicon carbide, e.g., dielectric structures and/or metal structures. Apart from trench gate electrodes and metal contact structures extending from an exposed surface on a front side of the transistor layer into the transistor layer, a top surface of the transistor layer may be substantially planar. A drain current of the transistor cells is controlled by controlling an electric field modulating the drain current through the transistor cells. The drain current passes through the current propagation regions.

The epitaxial growth transforms the foundation layer surface into an epitaxial interface between the foundation layer and the transistor layer. The epitaxial interface may be essentially planar or may include coplanar first sections and coplanar second sections at a vertical distance to the first sections. The first sections and the second sections may be connected by further sections. In other examples the interface 201 may be wavy or may have a zig-zag-like shape.

On opposite sides of the epitaxial interface, the content of one or more electrical active and/or electrical inactive impurities may differ significantly. For example, an average concentration of nitrogen, sulfur, iodine, oxygen and/or hydrogen in the transistor layer may differ significantly from an average concentration of the same element in the foundation layer.

The shielding structure may be formed directly along the epitaxial interface. The shielding structure may be composed of partial regions (shielding regions) that are separated from each other in at least one horizontal direction. For example, a rectangular, circular or oval gap with an opposite doping type as the shielding structure separates neighboring partial regions of the shielding structure. The shielding structure may include a plurality of stripe-shaped partial regions separated from each other along a horizontal direction by stripe-shaped regions with opposite doping type or may include shielding islands separated from each other along two orthogonal horizontal directions by a grid-like region with an opposite doping type. Sections of the shielding structure that are effective for the same transistor cell TC and the same current propagation region may also be referred to as shielding regions in the following. The shielding structure is not completely depleted under operation conditions within the safe operating area (SOA).

The steep change of the net dopant concentration along a vertical line through the pn junction between the shielding structure and a region of the first conductivity type in the transistor layer indicates the absence of an implantation tail as typically observed in context with high energy ion implantation through openings in a thick implantation mask. Without implantation tails, gaps in the shielding structure can be designed narrower and with better defined dimensions and doping distributions.

Alternatively or in addition, the net dopant concentration may change at the position of the pn junction by at least 1e17 1/cm³ per 0.1 μm, e.g., by at least 2e17 1/cm³ per 0.1 μm along a horizontal line parallel to the epitaxial interface and through a pn junction formed between the current propagation region and the shielding structure.

Alternatively or in addition, a width w0 of the current propagation region defined by the shortest horizontal distance between two points of zero net doping at opposite sides of the current propagation region may be at most 0.6 μm, for example at most 0.1 μm, a vertical extension v0 of the shielding structure may be at least 0.8 μm, for example at least 0.4 μm, and/or an aspect ratio v0/w0 of the gap in the shielding structure may be at least 0.3, at least 0.5, at least 1 or at least 5.

The current propagation region and a region of the shielding structure adjoining the current propagation region define a JFET structure that has a high impact on the on-state resistance RDSon of the semiconductor device. The various embodiments allow precisely defined JFET structures even at low lateral center-to-center distances between neighboring transistor cells TC. The number of transistor cells TC per area unit can be increased and the total on-state RDSon resistance further reduced. Furthermore, a JFET design with a high aspect ratio of channel length/channel width can facilitate an improved tradeoff between low on-state resistance RDSon and long short-circuit withstand time.

According to an embodiment, the foundation layer may include a current drift portion of the first conductivity type, wherein the current propagation region extends to the current drift portion.

The current drift portion may be a continuous horizontal layer laterally extending through the foundation layer in the vertical projection of some or all transistor cells formed in the transistor layer. Alternatively, the current drift portion may be part of a compensation structure. The current propagation region and the current drift portion may form a unipolar junction.

Along a vertical line orthogonal to the epitaxial interface and through a pn junction formed between the shielding structure and the current drift portion, a net dopant concentration may change by at least 1e16 1/cm³ per 0.1 μm, e.g., by at least 2e16 1/cm³ per 0.1 μm.

According to an embodiment, the semiconductor device may include a connection region of the second conductivity type, wherein the connection region extends through the transistor layer to the shielding structure and is in direct contact with the shielding structure along a first section of the epitaxial interface. A vertical dopant profile through the first section of the epitaxial interface may show a step at the epitaxial interface. The connection region may extend through the complete transistor layer or only through a vertical section of the transistor layer down to the shielding structure.

If an average dopant concentration in the connection region is higher or lower than an average dopant concentration in the shielding structure, then a vertical dopant profile through the connection region and the shielding structure can show a steep slope at the epitaxial interface with the net dopant concentration changing by at least 1e18 1/cm³ per 0.1 μm, e.g., by at least 2e18 1/cm³ per 0.1 μm. The steep slope can be a result of the transistor layer being formed after formation of the shielding structure in the foundation layer.

When a metal contact plug extends from a plane coplanar with a top surface of the transistor layer into the transistor layer, the connection region 160 may include a buried portion that extends from a bottom of the metal contact plug to or into the shielding structure, wherein a doping peak in the buried portion is formed directly below the metal for improved contacting.

According to an embodiment, the connection region may extend from a top surface of the transistor layer to the shielding structure.

The top surface can be parallel to the epitaxial interface. The epitaxial interface and the top surface are on opposite sides of the transistor layer. The connection region may extend down to the epitaxial interface or beyond such that the connection region extends into the foundation layer.

According to an embodiment, the transistor cell can be configured to control a current through a body region between a source region and a current collecting region, wherein the current collecting region may be electrically connected with the current propagation region.

The current collecting region may be in direct contact with the current propagation region or may be electrically connected with the current propagation region through a low-resistive ohmic connection, for example, through another doped region having a net dopant concentration different from the net dopant concentrations in the current collecting region and the current propagation region.

The current collecting region may receive the dopants defining the conductivity of the current collecting region during or after formation of the transistor layer. For example, the current collecting region may be in-situ doped during an epitaxial growth of the transistor layer.

The current propagation region may include a channel portion and a spreading portion. The channel portion extends through a gap in the shielding structure, wherein a vertical extension of the channel portion and a vertical extension of the shielding structure 260 are equal. The spreading portion separates the shielding structure and the current drift portion along the vertical direction. The channel portion and the spreading portion of the current propagation region may have the same dopant concentration. The dopant concentration in the spreading portion of the current propagation region may be higher than the dopant concentration in the current drift portion. For example, the dopant concentration in the spreading portion is at least two times or at least ten times higher than in the current drift portion.

According to an embodiment, the body region may separate the source region and the current collecting region in a horizontal direction parallel to the epitaxial interface. The transistor cell controls a horizontal current flow between the source region and the current collecting region through the body region.

According to another embodiment, the body region vertically separates the source region and the current collecting region. The transistor cell controls a vertical or almost vertical current flow between the source region and the current collecting region through the body region.

According to an embodiment, a trench gate structure may extend from a top surface of the transistor layer into the transistor layer, wherein the source region, the body region and the current collecting region are in direct contact with a sidewall of the trench gate structure.

According to an embodiment, the current collecting region and the current propagation region may be in direct contact with each other along a second section of the epitaxial interface, wherein a vertical dopant profile through the second section of the epitaxial interface shows a step at the epitaxial interface.

If an average dopant concentration in the current collecting region is higher or lower than an average dopant concentration in the current propagation region, then a vertical dopant profile through the current collecting region and the current propagation region can show a steep slope at the epitaxial interface. A net dopant concentration change is at least 2e17 1/cm³ per 0.1 μm, e.g., at least 4e17 1/cm³ per 0.1 μm. The steep slope may be the result of the transistor layer with the current collecting region being formed after formation of the current propagation region in the foundation layer.

According to an embodiment, the trench gate structure may end in the transistor layer and an auxiliary region of the second conductivity type may extend from a bottom of the trench gate structure to the shielding structure. The auxiliary region can be formed self-aligned to the trench gate structure.

According to an embodiment, the current propagation region may vertically extend through a gap in the shielding structure, wherein the gap has a vertical extension v0 and a horizontal width w0, and wherein an aspect ratio v0/w0 of the gap in the shielding structure may be at least 1.

The aspect ratio v0/w0 of the gap is equal to the aspect ratio of the channel portion of the current propagation region. The width w0 is measured parallel to the first horizontal direction. The aspect ratio v0/w0 can be at least 0.5. For example, the aspect ratio v0/w0 is at least 1, e.g., at least 5. A high aspect ratio v0/w0 of at least 1 or 5 facilitates a long maximum short-circuit withstand time.

According to an embodiment, the semiconductor device may further include a depletable first pillar region of the first conductivity type and depletable second pillar regions of the second conductivity type, wherein the first pillar region is formed in the foundation layer in direct contact with the current propagation region, and wherein the second pillar regions are formed in the foundation layer in direct contact with the shielding structure.

The doped first pillar regions 241 may alternate with doped second pillar regions 242 of the complementary conductivity type along the horizontal direction(s), wherein the first and second pillar regions 241, 242 form a compensation structure configured to be completely depleted at a nominal breakdown voltage of the semiconductor device within the SOA.

According to an embodiment, the transistor cells can be stripe-shaped with horizontal longitudinal axes along a first horizontal direction, wherein the first and second pillar regions can be stripe-shaped with horizontal longitudinal axes along the first horizontal direction.

The stripe-shaped transistor cells TC include stripe-shaped planar gate structures or stripe-shaped trench gate structures with horizontal longitudinal axes parallel to the first horizontal direction. The horizontal longitudinal axes of the gate structures and the horizontal longitudinal axes of the first and second pillar regions run parallel to each other.

According to an embodiment, the transistor cells are stripe-shaped with longitudinal axes along a first horizontal direction, and the first and second pillar regions are stripe-shaped with horizontal longitudinal axes oblique to the first horizontal direction.

The stripe-shaped transistor cells TC include stripe-shaped planar gate structures or stripe-shaped trench gate structures, wherein horizontal longitudinal axes of the stripe-shaped gate structures and horizontal longitudinal axes of the first and second pillar regions are inclined to each other in the horizontal plane by at least 10 degrees, e.g. by 30 degrees, by 45 degrees, or by 90 degrees.

According to an embodiment, the current propagation region may include a central portion formed in a gap in the shielding structure and a heavily doped sidewall portion between the central channel portion and the shielding structure.

The heavily doped sidewall portion may laterally separate the central portion and the shielding structure from each other. The central portion and the sidewall portion form a channel portion of the current propagation region.

According to an embodiment, a method of forming a semiconductor device may include forming a foundation layer based on single-crystalline silicon carbide, wherein the foundation layer includes a non-depletable shielding structure of a second conductivity type and a current propagation region of a first conductivity type extending from a foundation layer surface of the foundation layer through a gap in the shielding structure. A transistor layer may be formed on the foundation layer surface, wherein the transistor layer includes a transistor cell configured to control a current through the current propagation region. Along a vertical line orthogonal to an epitaxial interface between the transistor layer and the foundation layer and through a pn junction between the shielding structure and a region of the first conductivity type in the transistor layer, a net dopant concentration may change by at least 1e17 1/cm³ per 0.1 μm, at least 2e17 1/cm³ per 0.1 μm, or at least 4e17 1/cm³ per 0.1 μm.

At a pn junction between the current propagation region and the shielding structure, a net dopant concentration may change by at least 1e17 1/cm³ per 0.1 μm along a horizontal line parallel to the epitaxial interface.

According to an embodiment, forming the transistor layer may include growing the transistor layer on the foundation layer surface by epitaxy after forming the shielding structure in the foundation layer.

The current propagation region may include a spreading portion formed between and vertically separating the shielding region and a current drift portion of the first conductivity type, wherein the current drift portion is formed between the spreading portion and a drain layer on the rear side of the foundation layer, and wherein the dopant concentration in the shielding region is at least two times, e.g. at least ten times higher than in the current drift region. Formation of the spreading portion may include implanting dopants before epitaxial growth of the transistor layer.

According to an embodiment, forming the foundation layer may include forming depletable first pillar regions of the first conductivity type and depletable second pillar regions of the second conductivity in the foundation layer before forming the shielding structure, wherein the shielding structure is formed between the foundation layer surface and the first and second pillar regions.

Forming the foundation layer may include forming at least a lower section of the first pillar regions and second pillar regions in a first base layer for the foundation layer, then growing a second base layer of the foundation layer on a first base layer surface of the first base layer, and then forming the shielding structure or forming an upper section of the first pillar regions and second pillar regions and the shielding structure on the lower sections of the first pillar regions and second pillar regions.

According to an embodiment, forming the transistor layer may include forming a gate trench extending from a main surface of the transistor layer into the transistor layer, implanting dopants of the first conductivity type through a bottom of the gate trench to form an auxiliary region between the gate trench and the shielding structure, and forming a trench gate structure in the gate trench.

The dopants of the first conductivity type may be acceptor ions. The auxiliary region may extend from the bottom of the gate trench to or into the shielding structure.

According to an embodiment, forming the foundation layer may include forming, before forming the transistor layer, a channel trench in the gap of the shielding structure and filling the channel trench with doped semiconductor material to form at least a portion of the current propagation region.

The channel trench may be filled in course of the epitaxy process that forms the transistor layer. The gaps in the shielding structure may result from etching the channel trenches in a continuous shielding layer and the shielding structure may be obtained from the non-etched portion of the shielding layer.

According to an embodiment, dopant atoms may be implanted in sidewalls of the channel trench before filling the channel trench.

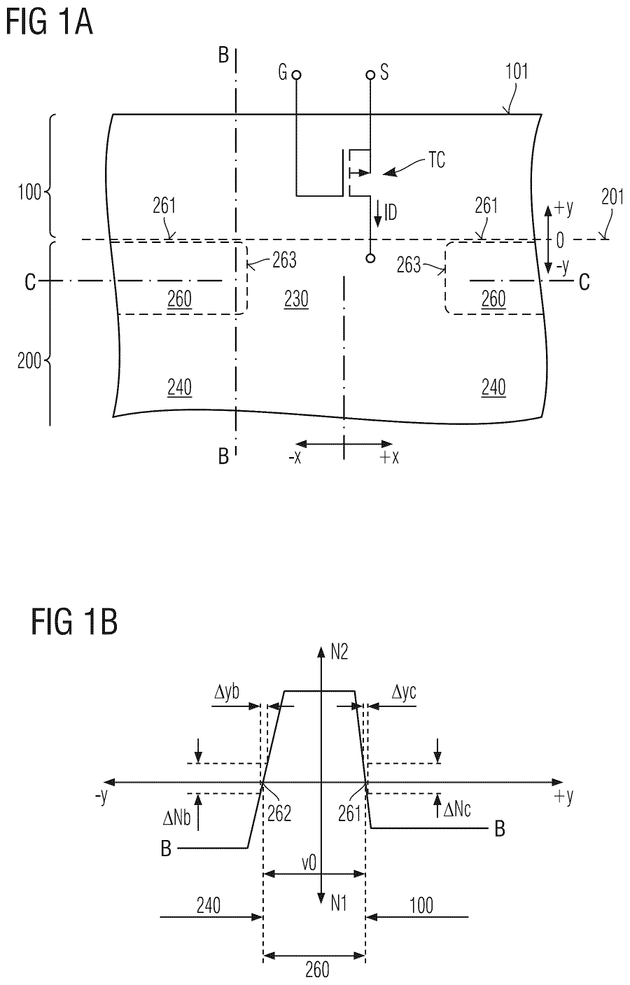

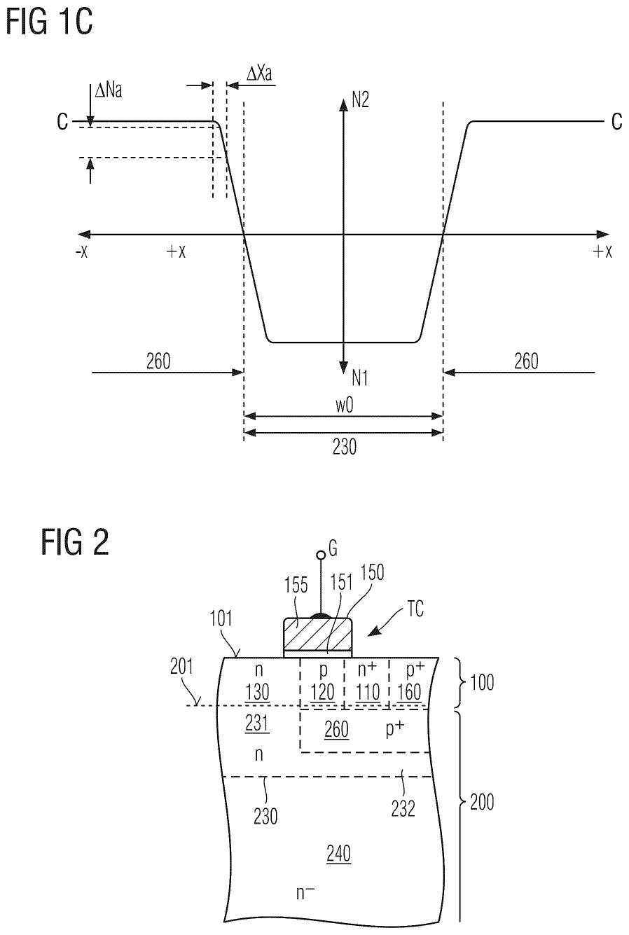

FIG. 1A shows a semiconductor device with a foundation layer 200 and a transistor layer 100. The foundation layer 200 and the transistor layer 100 are made of monocrystalline silicon carbide of the 4H polytype and are formed on opposite sides of a horizontal epitaxial interface 201.

The foundation layer 200 two essentially parallel, rectangular main surfaces, wherein a first main surface at a front side extends in a first horizontal plane and a second main surface at a rear side extends in a second horizontal plane. The foundation layer 200 has a thickness in a vertical direction orthogonal to the two horizontal planes.

An n conductive current drift portion 240, n conductive current propagation regions 230 and a non-depletable p conductive shielding structure 260 are formed as doped regions in the foundation layer 200.

The current drift portion 240 is formed as a continuous horizontal layer laterally extending through the foundation layer 200. The current propagation regions 230 are formed between partial regions of the shielding structure 260 and extend from the epitaxial interface 201 to the n conductive current drift portion 240. The n conductive current drift portion 240 and the n conductive current propagation regions 230 form horizontal unipolar junctions.

The shielding structure 260 extends from the epitaxial interface 201 into the foundation layer 200. Partial regions of the shielding structure 260 on opposite sides of a current propagation region 230 can be separated from each other or can be laterally connected to each other in a plane parallel to the cross-sectional plane to form a continuous, one-piece shielding structure 260. Within the shielding structure 260, the dopant concentration is approximately uniform along the horizontal directions. The shielding structure 260 does not become fully depleted under operation conditions within the safe operating area of the semiconductor device.

The transistor layer 100 is formed by epitaxy on the first main surface of the foundation layer 200 after formation of the shielding structure 260 in the foundation layer 200, whereby the silicon and carbon atoms continue the monocrystalline crystal lattice of the foundation layer 200. Apart from trench gate electrodes and/or metal contact structures extending from the exposed top surface 101 at a front side of the transistor layer 100 into the transistor layer 100, the top surface 101 of the transistor layer 100 is substantially planar. The transistor layer 100 includes a plurality of transistor cells TC. Load paths of the transistor cells TC between a source electrode S and the current drift portion 240 are electrically connected in parallel to each other.

A suitable potential applied to the gate electrode G of the transistor cells TC controls a load current through the transistor cells TC by field effect. The load current through the transistor cells TC passes through the current propagation regions 230.

FIG. 1B shows a vertical net dopant concentration gradient (vertical doping profile) along line B-B in FIG. 1A. N1 indicates a donor concentration (donor density). N2 indicates an acceptor concentration (acceptor density). The position of the horizontal axis indicates a plane of zero net doping.

A first section of line B-B crosses an upper pn junction 261 between the p conductive shielding structure 260 and an n conductive region in the transistor layer 100. Close to the upper pn junction 261, a net dopant concentration change ΔNc/Δyc is at least 1e17 1/cm³ per 0.1 μm, e.g., at least 2e17 1/cm³ per 0.1 μm.

A second section of line B-B crosses a lower pn junction 262 between the p conductive shielding structure 260 and the current drift portion 240. Close to the second pn junction 262, a net dopant concentration change ΔNb/Δyb is at least 1e16 1/cm³ per 0.1 μm, e.g., at least 2e16 1/cm³ per 0.1 μm. The net dopant concentration change ΔNc/Δyc at the upper pn junction 261 is greater (steeper) than the net dopant concentration change ΔNb/Δyb at the lower pn junction 262 by a factor 5 . . . 10.

A thickness v0 of the shielding structure 260 is defined by the vertical distance between the upper pn junction 261 and the lower pn junction 262. For a semiconductor device with trench gate, the thickness v0 may be equal to the distance between the bottom of the trench gate structure and the pn junction towards the drift layer. The thickness v0 of the shielding structure 260 is approximately uniform and in a range from 400 nm to 0.8 μm.

FIG. 1C shows a horizontal dopant concentration gradient in the foundation layer 200 in a horizontal plane intersecting the current propagation region 230 and the shielding structure 260 as indicated by line C-C in FIG. 1A.

At the vertical pn junctions 263 between the shielding structure 260 and the current propagation region 230, the net dopant concentration change ΔNa/Δxa is at least 1e17 1/cm³ per 0.1 μm, e.g., at least 2e17 1/cm³ per 0.1 μm.

A width w0 of the current propagation region 230 is defined by the horizontal distance between the vertical pn junctions 263 on opposite sides of the current propagation region 230. The width w0 of the current propagation region 230 is in a range from 100 nm to 600 μm.

An aspect ratio v0/w0 of a gap in the shielding structure 260 is at least 1, for example at least 5. The current propagation region 230 completely fills the gap and forms the channel region of a JFET structure that effects the on-state resistance RDSon. A JFET design with high aspect ratio v0/w0 of length/width enables an improved tradeoff between low RDSon and long short circuit withstand time.

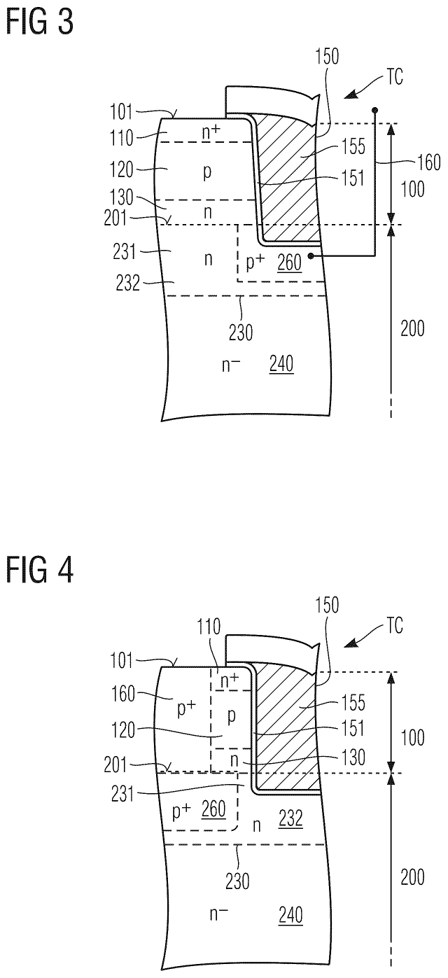

Each of FIG. 2, FIG. 3 and FIG. 4 shows details of different transistor cells TC in combination with p conductive connection regions 160 extending from the top surface 101 of the transistor layer 100 down to the p conductive shielding structure 260.

Each transistor cell TC includes an n conductive source region 110, a p conductive body region 120, an n conductive current collecting region 130, a gate conductor 155 electrically connected with a gate electrode G, and a gate dielectric 151 separating the gate conductor 155 and the body region 120. The body region 120 separates the source region 110 and the current collecting region 130 from each other. A potential applied to the gate electrode G controls a current between the source region 110 and the current collecting region 130 through the body region 120 by field effect.

The current collecting region 130 and the current propagation region 230 are in direct contact with each other and can have the same dopant concentration or can form a unipolar junction. The current collecting region 130 may receive the dopants defining its conductivity during or after formation of the transistor layer 100. For example, the current collecting region 130 may be in-situ doped during an epitaxial growth of the transistor layer 100.

The connection regions 160 are in direct contact with the shielding structure 260, wherein the connection regions 160 and the shielding structure 260 form horizontal unipolar junctions along first sections of the epitaxial interface 201. A vertical dopant profile through the first section of the epitaxial interface 201 shows a step at the epitaxial interface 201.

FIG. 2 shows a semiconductor device with planar gate structures 150, wherein the gate conductor 155 and the gate dielectric 151 are formed on the top surface 101 of the transistor layer 100. The source region 110, the body region 120 and the current collecting region 130 are formed in the transistor layer 100 along the top surface 101 in this order, wherein the body region 120 separates the source region 110 and the current collecting region 130 in a horizontal direction parallel to the epitaxial interface 201.

A first vertical pn junction is formed between the current collecting region 130 and the body region 120. A second vertical pn junction is formed between the body region 120 and the source region 110. The gate conductor 155 is formed on the transistor layer 100 and spans from approximately above the first vertical pn junction to approximately above the second vertical pn junction. The gate dielectric 151 separates the gate conductor 155 and the transistor layer 100 from each other. The gate conductor 155 is capacitively coupled to the body region 120.

A shielding structure 260 is formed along the epitaxial interface 201 of the foundation layer 200 in direct contact with the body region 120 and the source region 110. A p conductive connection region 160 with a higher average dopant concentration than the body region 120 extends next to the source region 110 from the top surface 101 of the transistor layer 100 to the shielding structure 260.

The current propagation region 230 includes a channel portion 231 and a spreading portion 232. The channel portion 231 extends through a gap in the shielding structure 260 or between two neighboring stipe-shaped partial regions of the shielding structure 260 (shielding regions). A vertical extension of the channel portion 231 and a vertical extension of the shielding structure 260 are equal. The spreading portion 232 separates the shielding structure 260 and the current drift portion 240 along the vertical direction. The channel portion 231 and the spreading portion 232 of the current propagation region 230 have the same dopant concentration.

FIG. 3 and FIG. 4 show semiconductor devices with trench gate structures 150 that extend from the top surface 101 of the transistor layer 100 into or through the transistor layer 100. Each trench gate structure 150 includes a gate conductor 155 and a gate dielectric 151, wherein the gate dielectric 151 lines a gate trench, and the gate conductor 155 fills the rest of the gate trench. The gate dielectric 151 separates the gate conductor 155 from the transistor layer 100 and, if applicable, from the foundation layer 200. The source region 110, the body region 120 and the current collecting region 130 are formed along at least one sidewall of the trench gate structure 150 in this order and are in direct contact with a sidewall of the trench gate structure 150. The source region 110 extends from the top surface 101 into the transistor layer 100. The body region 120 vertically separates the source region 110 and the current collecting region 130.

FIG. 3 shows a semiconductor device with trench gate structures 150 and transistor cells TC with one-sided transistor channel. The channel portion 231 of the current propagation region 230 is formed at a lateral distance from the trench gate structure 150. A bottom portion of the trench gate structure 150 is in direct contact with the shielding structure 260. The connection regions 160 can be formed at a side of the trench gate structures 150 opposite to the body regions 120 and extend from the top surface 101 down to or into the shielding structure 260 or at the same side as the transistor channel in a plane parallel to the cross-sectional plane.

In FIG. 4, the channel portion 231 of the current propagation region 230 is formed with no lateral distance to the trench gate structure 150. The channel portion 231 laterally separates a bottom portion of the trench gate structure 150 from the shielding structure 260.

In each of the semiconductor devices of FIG, FIG. 3 and FIG. 4, the current collecting regions 130 and the current propagation regions 230 are in direct contact with each other along second sections of the epitaxial interface 201. The current collecting regions 130 and the channel portions 231 of the current propagation regions 230 can have the same dopant content. Otherwise, a vertical dopant profile through the second sections of the epitaxial interface 201 can have a steep step at the epitaxial interface 201.

FIG. 5 refers to an example with an average donor concentration ND1 in the current collecting region 130 being lower than an average donor concentration ND2 in the current propagation region 230. The vertical dopant profile through the current collecting region 130 and the current propagation region 230 shows a steep slope at the epitaxial interface 201. A net dopant concentration change is at least 2e17 1/cm³ per 0.1 μm, e.g., at least 4e17 1/cm³ per 0.1 μm. The steep slope can be the result of the transistor layer 100 with the current collecting region 130 being formed by epitaxy after formation of the current propagation region 230 in the foundation layer 200.

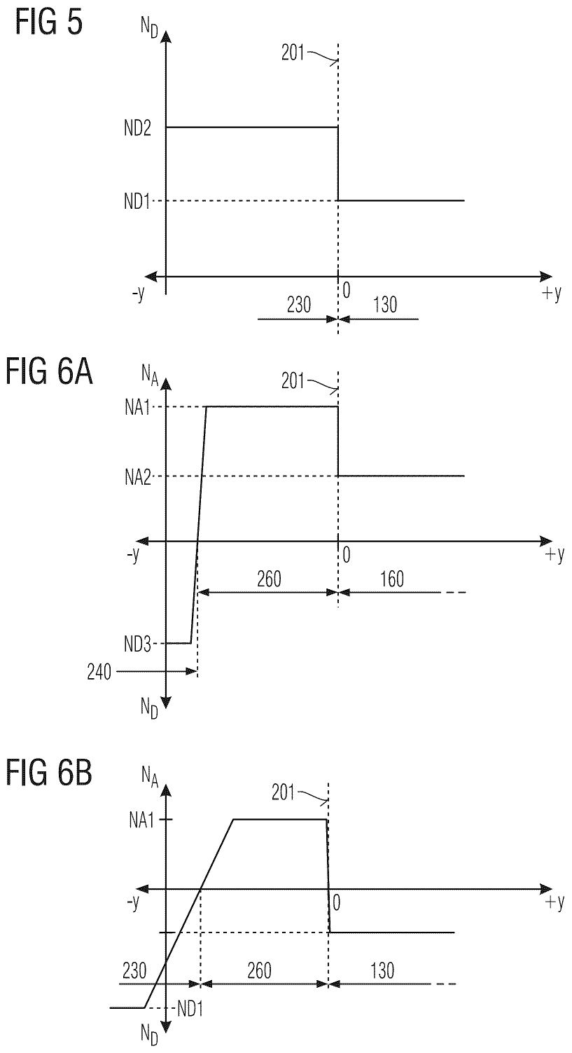

FIG. 6A refers to an example with an average acceptor concentration NA2 in the connection region 160 being lower than an average acceptor concentration NA1 in the shielding structure 260. Then the vertical dopant profile through the connection region 160 and the shielding structure 260 can show a steep slope at the epitaxial interface 201. A net dopant concentration change is at least 1e18 1/cm³ per 0.1 μm, e.g., at least 2e18 1/cm³ per 0.1 μm. The steep slope can result from that the transistor layer 100 is formed after formation of the shielding structure 260 in the foundation layer 200.

FIG. 6B refers to transistor cells with trench gate structures. For example, in FIG. 3 the current propagation region 230 may include a layer-like spreading portion 232 formed between the shielding structure 260 and the current drift portion 240. When the dopants for the spreading portion 232 are implanted through the transistor layer 100, an implant tail reaches up into the current collecting region 130 and the body region 120. In contrast, the formation of the transistor layer 100 after implantation of the dopants for the spreading portion 232 and the shielding region 260 forms a well-defined sharp transition at the pn junction between the shielding region 260 and the current collecting region 130. The doping in the body region 120 and the current collecting region 130 can be precisely defined. The net dopant concentration change at the epitaxial interface 201 is at least 1e17 1/cm³ per 0.1 μm, e.g., at least 2e17 1/cm³ per 0.1 μm.

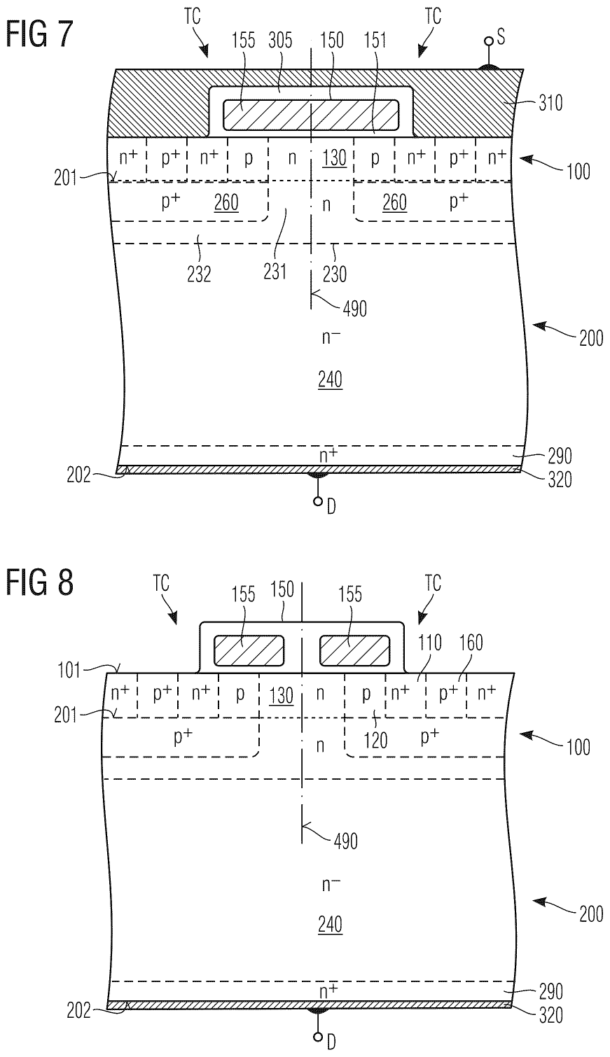

FIG. 7 and FIG. 8 show symmetric transistor cells TC with planar gate structures 150. The planes of symmetry 490 are orthogonal to the top surface 101 of the transistor layer 100 and run in the lateral centers of a current collecting region 130 and a channel portion 231 of a current propagation region 230. The current collecting region 130 and the channel portion 231 are shared between the two symmetric transistor cells TC.

The current drift portion 240 is homogenously doped and vertically separates the current propagation region 230 from a heavily doped drain layer 290, which is formed along a rear side surface 202 of the foundation layer 200. A dopant concentration in the drain layer 290 is sufficiently high to form an ohmic contact with a rear side metallization 320, which forms or is electrically connected with a drain electrode D of the semiconductor device. At the front side, an interlayer dielectric 305 separates the gate conductor 155 from a front side metallization 310. The front side metallization 310 forms ohmic contacts with the source regions 110 and the connection regions 160 and forms or is electrically connected with a source electrode S of the semiconductor device.

In FIG. 7, the gate conductor 155 completely spans the current collecting region 130. In FIG. 8, the gate conductor 155 is split in two parts and is missing over a central portion of the current collecting region 130.

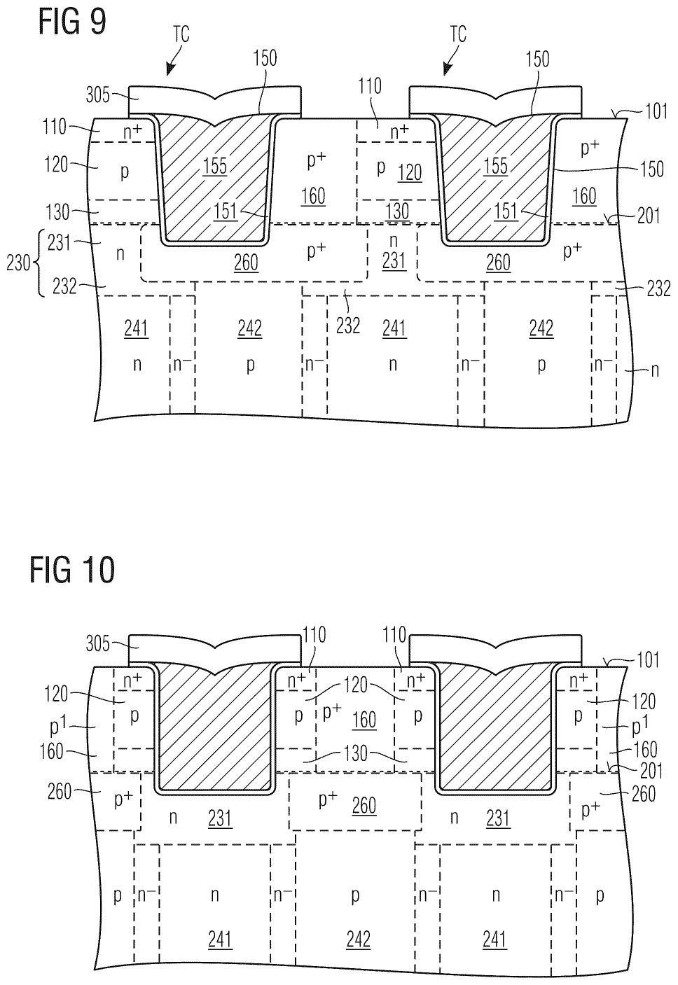

The semiconductor device illustrated in FIG. 9 includes transistor cells TC with one-sided transistor channel as described with reference to FIG. 3. Stripe-shaped trench gate structures 150 with horizontal longitudinal axes along a first horizontal direction orthogonal to the cross-sectional plane extend from the top surface 101 of the transistor layer 100 into the shielding structure 260. The channel portions 231 of the current propagation region 230 are formed at a lateral distance from the trench gate structures 150. The connection regions 160 are formed at a side of the trench gate structures 150 opposite to the body regions 120 and extend along the sidewalls of the trench gate structures 150 from the top surface 101 down to the shielding structure 260.

The semiconductor device illustrated in FIG. 10 includes transistor cells TC with two-sided transistor channels as described with reference to FIG. 4. Stripe-shaped trench gate structures 150 with horizontal longitudinal axes along a first horizontal direction orthogonal to the cross-sectional plane extend down to or into the foundation layer 200 and the channel portions 231 of the current propagation regions 230. The channel portions 231 of the current propagation regions 230 are in direct contact with the trench gate structures 150. The connection regions 160 extend between neighboring transistor cells TC from the top surface 101 down to the shielding structure 260. The shielding structure 260 includes stripe-shaped partial regions with horizontal longitudinal axes orthogonal to the cross-sectional plane or forms a grid with the channel portions 231 of the current propagation regions formed in the meshes of the grid.

The semiconductor devices in FIG. 9 and FIG. 10 further include depletable n conductive first pillar regions 241 and depletable second p conductive pillar regions 242. The first pillar regions 241 are formed in the foundation layer 200 in direct contact with the current propagation regions 230. The second pillar regions 242 are formed in the foundation layer 200 in direct contact with the shielding structure 260.

The n conductive first pillar regions 241 and the p conductive second pillar regions 242 are stripe-shaped with horizontal longitudinal axes along the first horizontal direction. The n conductive first pillar regions 241, the p conductive second pillar regions 242 and the trench gate structures 150 run parallel to each other. The n conductive first pillar regions 241 and the p conductive second pillar regions 242 alternate along a second horizontal direction (x-axis) orthogonal to the first horizontal direction. The first and second pillar regions 241, 242 form a compensation structure configured to be completely depleted at a nominal breakdown voltage of the semiconductor device within the SOA.

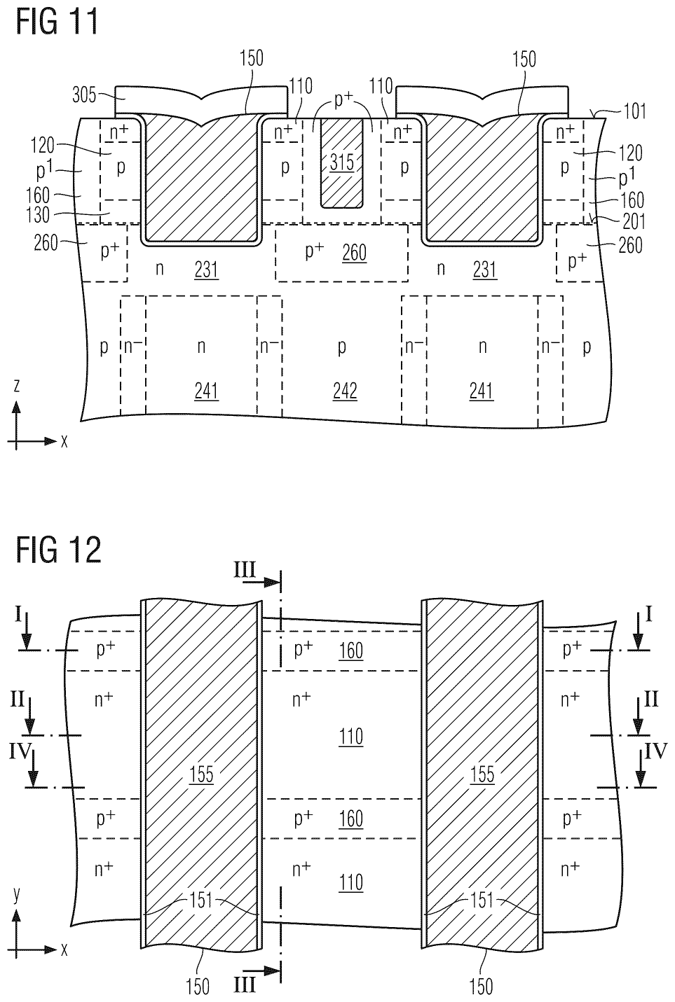

In FIG. 11, metal contact plugs 315 extend from the top surface 101 into the connection regions 160 in the transistor layer 100. The connection regions 160 are in contact with the bottom and the sidewalls of the metal contact plugs 315. The metal contact plugs 315 and the connection regions 160 form low-resistive ohmic contacts. The connection regions 160 include portions that extend from the bottom of the metal contact plugs 315 to or into the shielding structure 260, wherein a doping peak directly below the metal contact plug 315 improves the ohmic contact. Alternatively, the metal contact plugs 315 may extend into the shielding structure 260.

While in FIG. 10 and FIG. 11 the connection regions 160 are formed between adjacent source regions 110 of neighboring stripe-shaped transistor cells TC and alternate with the source regions 110 along the second horizontal direction (x-axis), FIG. 12 shows the connection regions 160 alternating with the source regions 110 along the first horizontal direction (y-axis). Each connection region 160 extends along the second horizontal direction (x-axis) from a first trench gate structure 150 to a neighboring second trench gate structure 150. Each source region 110 extends along the second horizontal direction from the first trench gate structure 150 to the neighboring second trench gate structure 150. Connection regions 160 and source regions 110 strictly alternate along the first horizontal direction (y-axis).

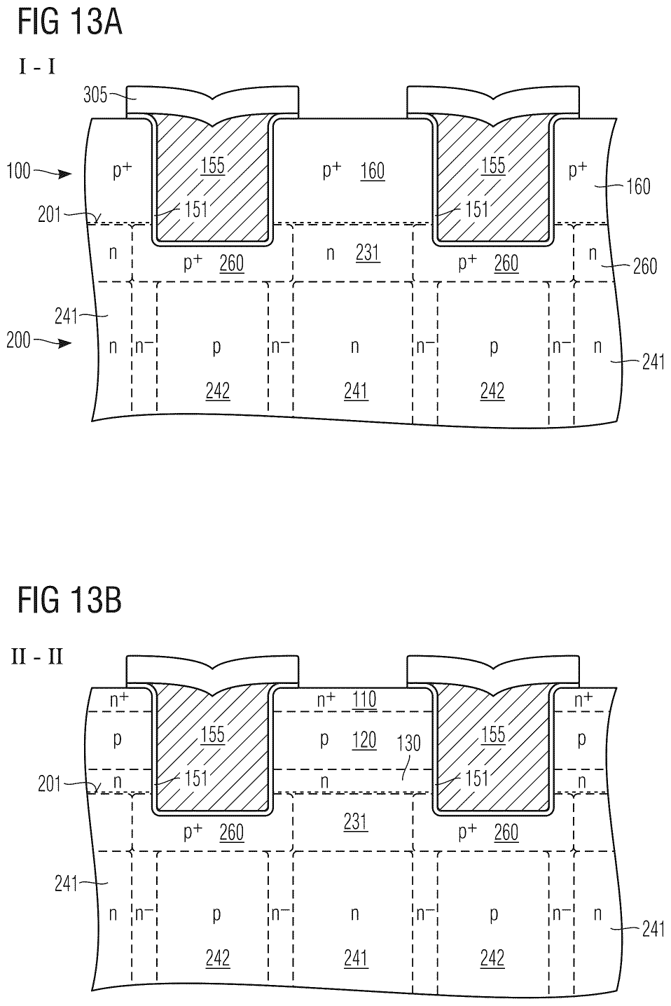

FIG. 13A and FIG. 13B show parallel cross-sections for the planar transistor cell layout of FIG. 12 for an example with the n conductive pillar regions 241 in direct contact with the channel portions 231 of the current propagation regions.

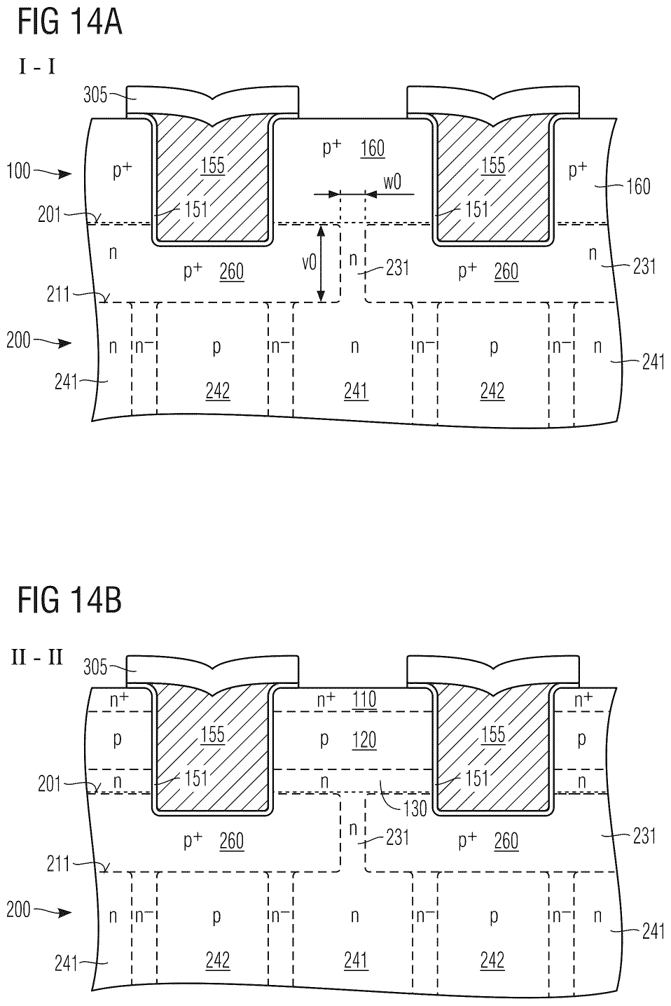

FIG. 14A and FIG. 14B show parallel cross-sections for the planar transistor cell layout of FIG. 12 for an example with narrow channel portions 231. An aspect ratio v0/w0 of the channel portions 231 is at least 1, or at least 5.

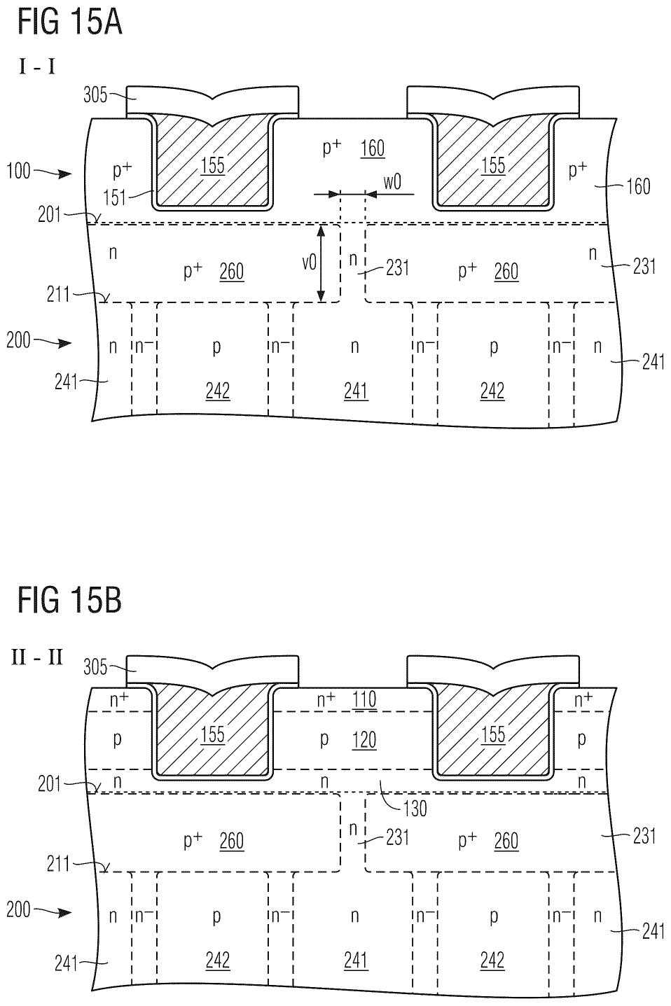

In FIG. 15A and FIG. 15B the trench gate structures 150 are completely formed in the transistor layer 100 and end at a distance to the foundation layer 200.

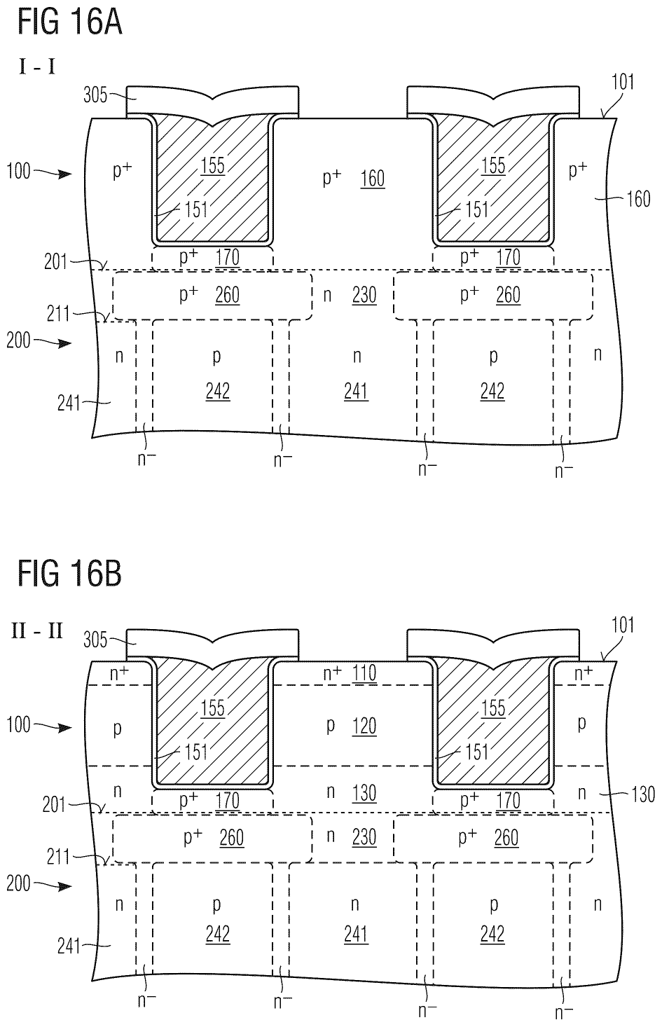

In FIG. 16A and FIG. 16B, the trench gate structures 150 end in the transistor layer 100. P conductive auxiliary regions 170 extend from a bottom of the trench gate structures 150 to the shielding structure 260. The p conductive auxiliary regions 170 and the shielding structure 260 are in direct contact and form a unipolar junction along the epitaxial interface 201. A vertical dopant profile through the unipolar junction between a p conductive auxiliary region 170 and the shielding structure 260 can have a steep slope at the epitaxial interface 201.

The auxiliary region 170 can be formed self-aligned to the trench gate structure 150. Alignment requirements between the trench gate structure 150 in the transistor layer 100 and the gaps in the shielding structure 260 in the foundation layer 200 are more relaxed.

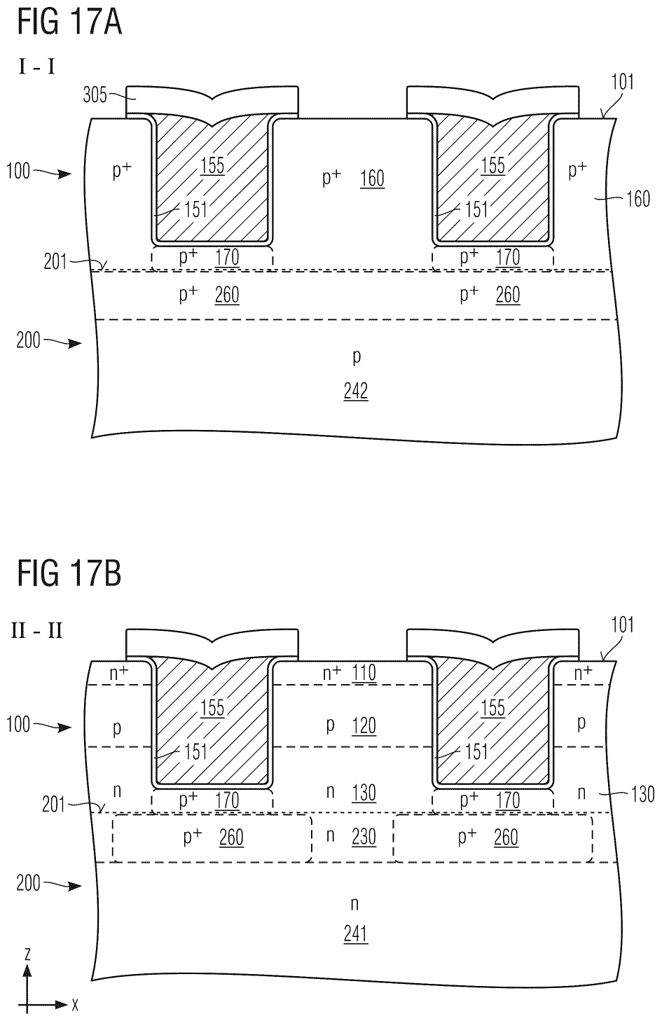

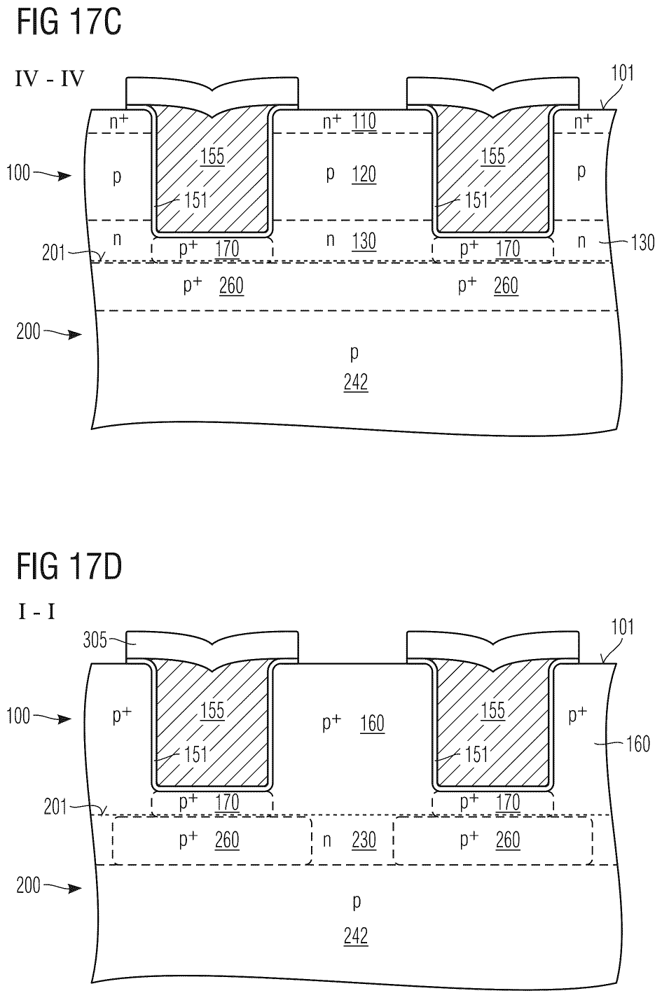

In FIG. 17A, FIG. 17B, FIG. 17C, and FIG. 17D, stripe-shaped first and second pillar regions 241, 242 have horizontal longitudinal axes orthogonal to the second horizontal direction (x-axis). The stripe-shaped transistor cells include stripe-shaped planar gate structures 150 or stripe-shaped trench gate structures 150 with horizontal longitudinal axes parallel to the first horizontal direction. The first and second pillar regions 241, 242 run orthogonal to the gate structures 150.

FIG. 17A, FIG. 17B, and FIG. 17C show a grid-shaped shielding structure 260 with openings directly below and in direct contact with the n conductive current collecting regions 130.

As illustrated in FIG. 17A, the shielding structure 260 connects the p conductive second pillar regions 242 with a plurality of connection regions 160.

According to FIG. 17B, n conductive current propagation regions 230 in the openings of the shielding structure 260 connect each n conductive first pillar region 241 with a plurality of current collecting regions 130.

FIG. 17C shows that a p conductive second pillar region 242 wider than the p+ conductive connection region 160 undercuts the comparatively wide transistor region with the n+ conductive source regions 110 and n conductive current collecting regions 130. In the illustrated cross-section, the shielding region 260 is formed between the second pillar regions 242 and the n conductive current collecting regions 130.

FIG. 17D shows a shielding structure 260 with stripe-shaped partial regions having horizontal longitudinal axes along the first horizontal direction parallel to the gate structure 150. Each partial region of the shielding structure 260 connects a p conductive second pillar region 242 with a plurality of connection regions 160. N conductive current propagation regions 230 laterally separate the partial regions of the shielding structure 260 from each other.

Similar as illustrated in FIG. 17B, the conductive current propagation regions 230 connect each n conductive first pillar region 241 with a plurality of current collecting regions 130.

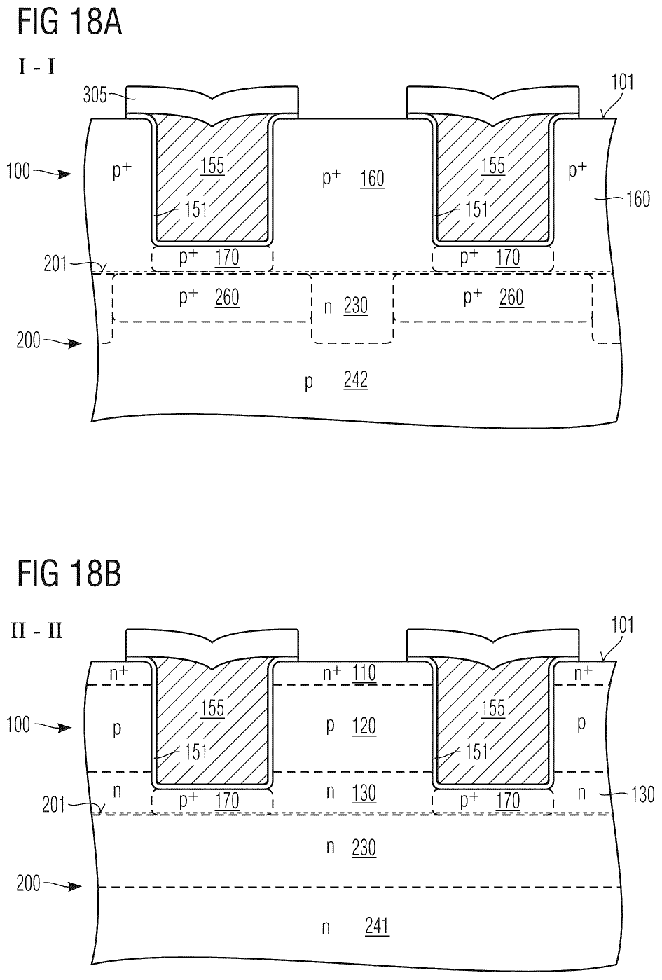

In FIG. 18A and FIG. 18B, the shielding structure 260 is patterned along the first horizontal direction. The shielding structure 260 includes shielding islands laterally separated from each other along the first and second horizontal directions above the n conductive first pillars 241. At cost of area for the shielding structure 260, the area for the current propagation regions is increased to improve efficiency of the current spreading function of the current propagation region 230.

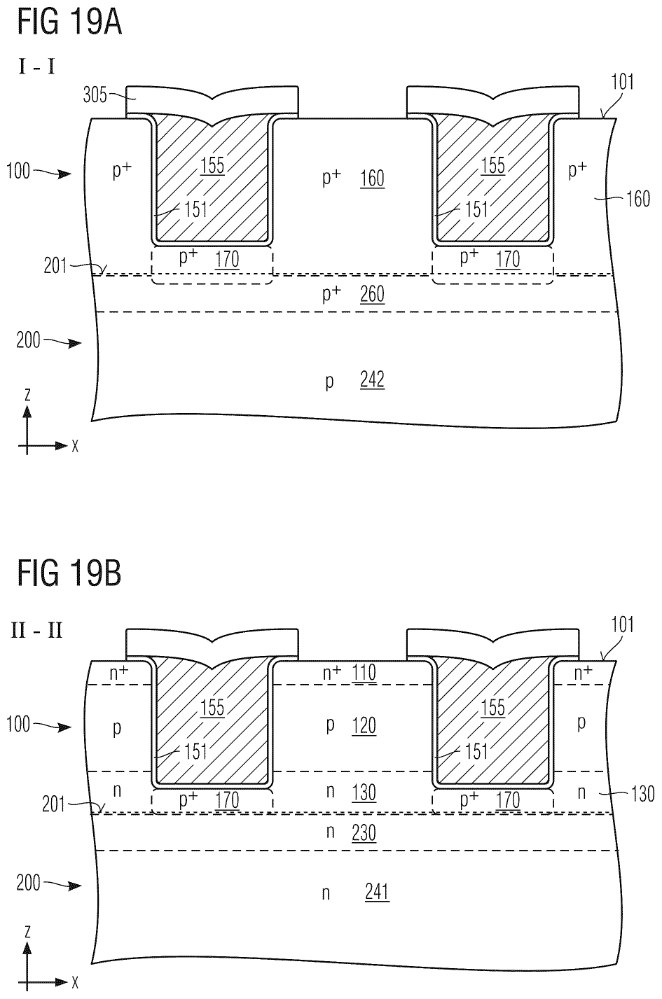

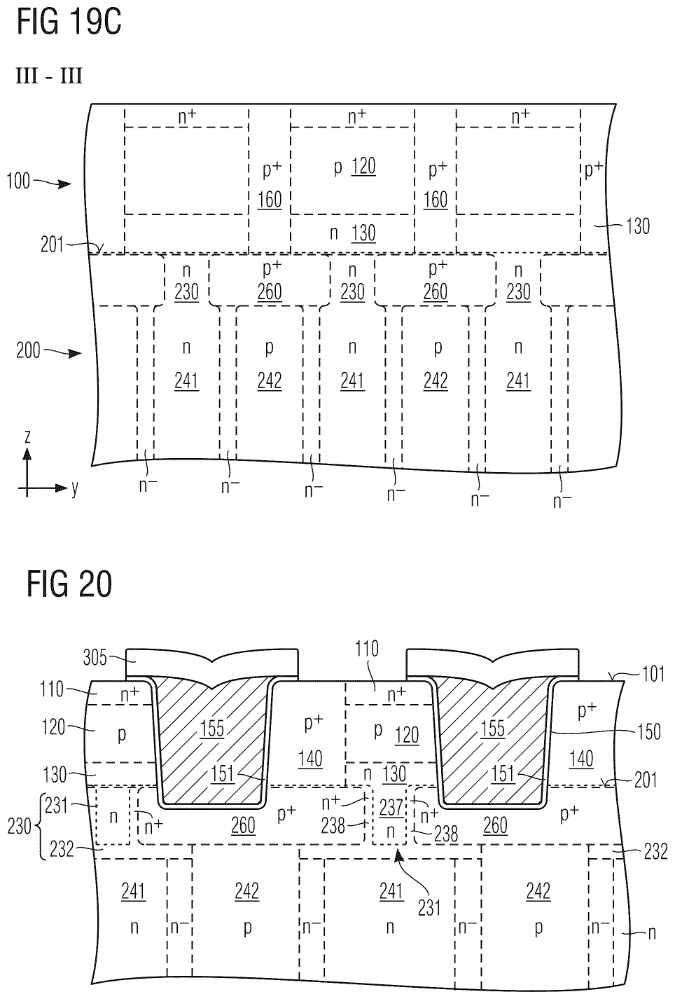

In FIG. 19A to FIG. 19C, the n conductive first pillar regions 241 and the p conductive second pillar regions 242 run with the horizontal longitudinal axes parallel to the second horizontal direction (x-axis) and laterally adjusted to the source regions 110 and the connection regions 160 in the transistor layer 100. The shielding structure 260 includes stripe-shaped partial regions with horizontal longitudinal axes parallel to the second horizontal direction (x-axis). Stripe-shaped current propagation regions 230 above the n conductive first pillars 241 laterally separate the stripe-shaped partial regions of the shielding structure 260 from each other. Each stripe-shaped current propagation regions 230 connects an n conductive first pillar region 241 to a plurality of current collecting regions 130. Each stripe-shaped partial region of the shielding structure 260 connects a p conductive second pillar region 242 to a plurality of connection regions 160.

FIG. 20 shows a current propagation region 230 that includes a channel portion 231 with a central portion 237 and heavily doped sidewall portions 238 between the central portion 237 and the shielding structure 260. The heavily doped sidewall portions 238 separate the central portion 237 from the shielding structure 260. The heavily doped sidewall portions 238 allow a precise tuning of the JFET structure and can result from a tilted ion implantation.

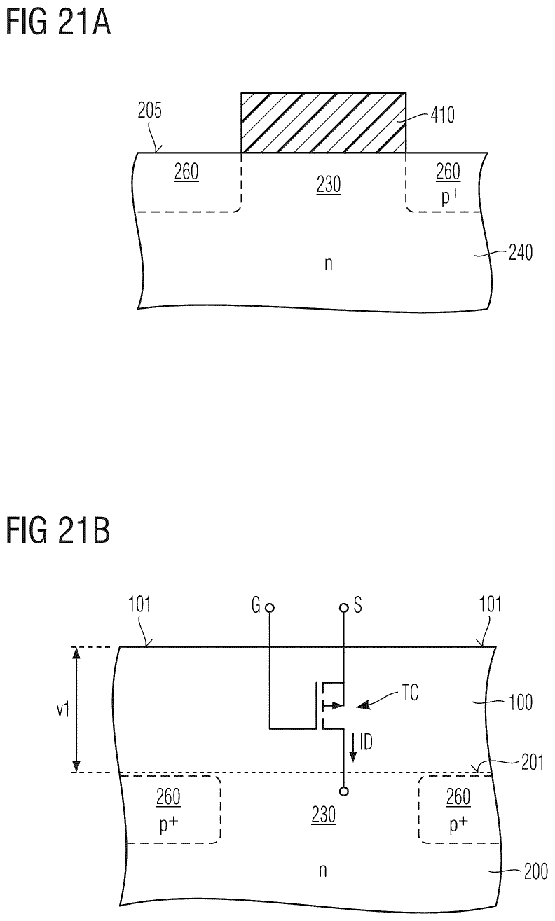

FIG. 21A to 21B show a method of manufacturing a semiconductor device. A first implantation mask 410 is formed on a foundation layer surface 205 at a front side of a foundation layer 200 by photolithography, wherein the foundation layer 200 is based on single-crystalline silicon carbide with an n type background doping. Acceptor ions are implanted through openings in the first implantation mask 410.

FIG. 21A shows a p conductive shielding structure 260 obtained by activating the acceptor ions implanted in regions of the foundation layer 200 exposed by the first implantation mask 410. A portion of the foundation layer 200 covered by the first implantation mask 410 forms an n conductive current propagation region 230. A portion of the foundation layer 200 below the shielding structure 260 and the current propagation region 230 forms a current drift region 240.

Then a transistor layer 100 is formed on the foundation layer surface 205 by epitaxy. Doped regions and gate structures of transistor cells TC are formed in the transistor layer 100.

FIG. 21B shows the transistor layer 100 and the foundation layer 200 forming a horizontal epitaxial interface 201 in the plane of the foundation layer surface 205 of FIG. 21A. The transistor cells TC in the transistor layer 100 control a drain current IC through the current propagation region 230 in the foundation layer 200. Along a vertical line orthogonal to the epitaxial interface 201 and through a pn junction between the shielding structure 260 and an n conductive region in the transistor layer 100, a net dopant concentration changes by at least 1e17 1/cm³ per 0.1 μm.

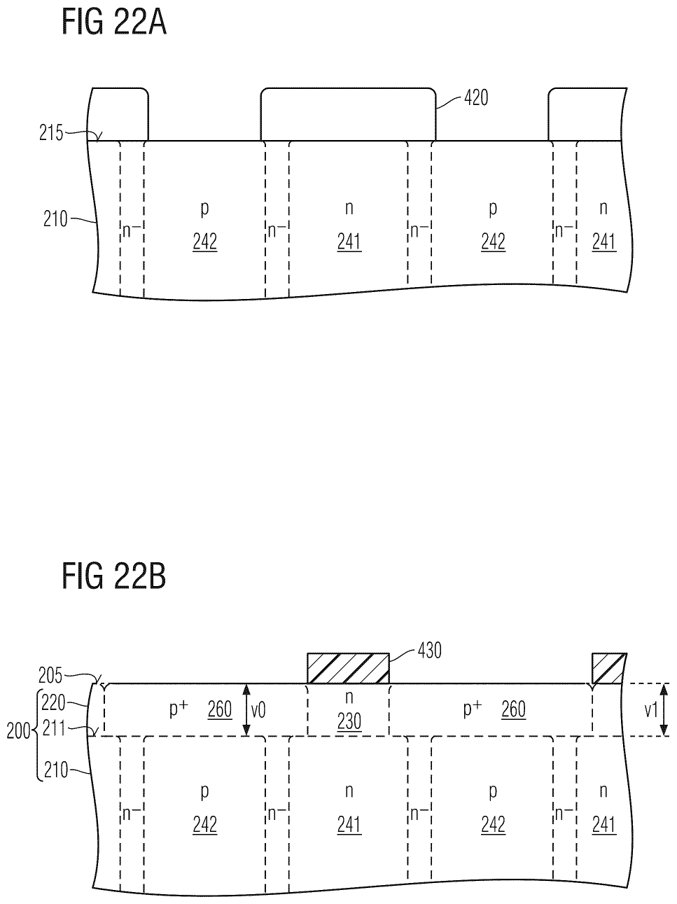

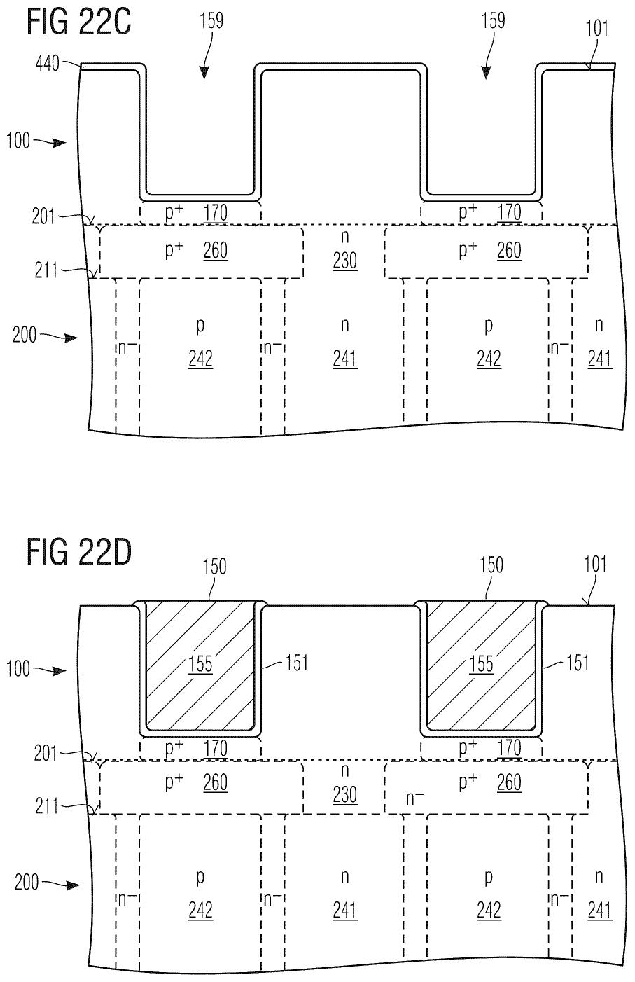

FIG. 22A to 22D show a method using epitaxy on base layers with previously formed doped regions. A first auxiliary implantation mask 420 is formed on a first base layer surface 215 at a front side of a first base layer 210 by photolithography, wherein the first base layer 210 is based on single-crystalline silicon carbide with an n type background doping. Acceptor ions are implanted through openings in the first auxiliary implantation mask 420.

FIG. 22A shows p conductive second pillar regions 242 obtained from activated acceptor ions implanted through the openings in the auxiliary implantation mask 420 and n conductive first pillar regions 241 formed in sections of the first base layer 210 covered by the auxiliary implantation mask 420.

The first auxiliary implantation mask 420 is removed and a second base layer 220 is formed on the first base layer surface 215 by epitaxy. The second base layer 220 may be in-situ doped with donor atoms. The first base layer 210 and the second base layer 220 form a foundation layer 200 with an exposed foundation layer surface 205. A second auxiliary implantation mask 430 is formed on the foundation layer surface 205 using photolithography. Acceptor atoms are implanted into the second base layer 220 by ion implantation.

FIG. 22B shows a p conductive shielding structure 260 obtained by activating the acceptor ions implanted through the openings in the second auxiliary implantation mask 430 and n conductive current propagation regions 230 formed in sections of the second base layer 220 covered by the second auxiliary implantation mask 430. Each p conductive shielding structure 260 is in direct contact with a p conductive second pillar region 242. Each n conductive current propagation region 230 is in direct contact with an n conductive first pillar region 241.

An epitaxial base interface 211 is formed between the first base layer 210 and the second base layer 220. A thickness v1 of the second base layer 220 and a vertical extension v0 of the shielding structure 260 are at least approximately equal.

The second auxiliary implantation mask 430 is removed and a transistor layer 100 is grown on the foundation layer surface 205 by epitaxy. The transistor layer 100 may be in-situ doped with donor atoms or acceptor atoms. A trench etch mask is formed on a top surface 101 of the transistor layer 100. Gate trenches 159 are etched into the transistor layer 100 above the shielding structure 260. A sacrificial oxide 440 is formed on exposed surfaces of the transistor layer 100. Acceptor atoms are implanted through the bottom of the gate trenches 159.

FIG. 22C shows p conductive auxiliary regions 170 obtained from activated acceptor ions implanted through the bottom of the gate trenches 159. Each p conductive auxiliary region 170 is in direct contact with the p conductive shielding structure 260. The auxiliary regions 170 extend from the trench gate structures 150 to the shielding structure 260.

The sacrificial oxide 440 is removed. A dielectric liner is formed on exposed surfaces of the transistor layer 100, e.g. by oxidation and/or deposition. A conductive material, e.g. heavily doped polycrystalline silicon, is deposited and removed from the top surface 101.

FIG. 22D shows gate structures 150 with a gate conductor 155 formed from the deposited conductive material filling the gate trenches 159 of FIG. 22C.

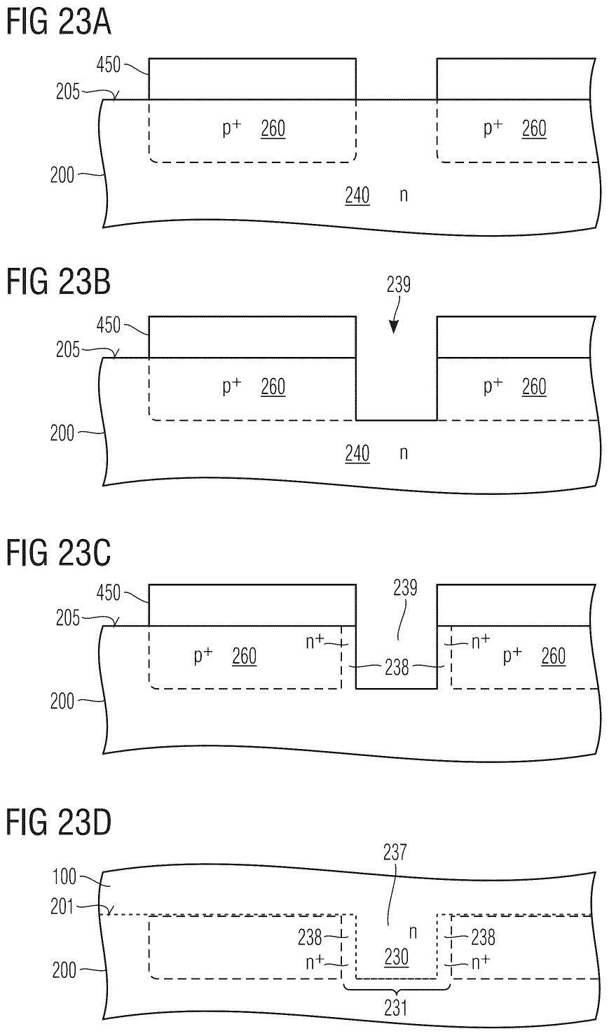

FIG. 23A to FIG. 23D show a method for defining the JFET structure more precisely. A hard mask 450 is formed on a foundation layer surface 205 at a front side of a foundation layer 200, wherein the foundation layer 200 includes a shielding structure 260 or a continuous p conductive layer formed along the foundation layer surface 205.

As illustrated in FIG. 23A, the hard mask 450 covers the shielding structure 260 and exposes portions of the foundation layer 200 between or surrounded by the shielding structure 260. Using the hard mask 450 as etch mask, channel trenches 239 are etched into the foundation layer 200.

FIG. 23B shows a channel trench 239. Sidewalls of the channel trench 239 expose the p conductive shielding structure 260. Donor atoms are implanted by tilted ion implantation through the sidewalls of the channel trench 239.

According to FIG. 23C, heavily doped n conductive sidewall portions 238 of a channel portion of a current propagation region are formed on opposite sides of the channel trench. Then a transistor layer 100 is grown on the foundation layer surface 205 by epitaxy as described above. The transistor layer 100 may be in-situ doped with donor atoms.

According to FIG. 23D, a section of the grown transistor layer 100 fills the channel trench 239 of FIG. 23C. The in-situ doped section of the transistor layer 100 in the channel trench 239 of FIG. 23C forms a lightly doped central portion 237 of the channel portion 231 of a current propagation region.

1. A semiconductor device, comprising:
a foundation layer based on single-crystalline silicon carbide and comprising a current propagation region of a first conductivity type and a non-depletable shielding structure of a second conductivity type; and
a transistor layer based on epitaxially grown single-crystalline silicon carbide and comprising a transistor cell (TC) configured to control a current through the current propagation region,
wherein the transistor layer was formed on the foundation layer after formation of the shielding structure in the foundation layer such that an epitaxial interface forms between the foundation layer and the transistor layer;
wherein the current propagation region extends from the epitaxial interface between neighboring partial regions of the shielding structure; and
wherein along a vertical line orthogonal to the epitaxial interface and through a pn junction between the shielding structure and a region of the first conductivity type in the transistor layer, a net dopant concentration changes by at least 1e17 1/cm³ per 0.1 μm at the position of the pn junction.

2. The semiconductor device according to claim 1,
wherein the foundation layer further comprises a current drift portion of a first conductivity type, and wherein the current propagation region extends to the current drift portion.

3. The semiconductor device according to claim 1, further comprising:
a connection region of the second conductivity type, wherein the connection region extends through the transistor layer to the shielding structure and is in direct contact with the shielding structure along a first section of the epitaxial interface, and wherein a vertical dopant profile through the first section of the epitaxial interface shows a step at the epitaxial interface.

4. The semiconductor device according to claim 3,
wherein the connection region extends from a top surface of the transistor layer to the shielding structure.

5. The semiconductor device according to claim 1,
wherein the transistor cell is configured to control a current through a body region between a source region and a current collecting region, and wherein the current collecting region is electrically connected with the current propagation region.

6. The semiconductor device according to claim 5,
wherein the body region separates the source region and the current collecting region in a horizontal direction parallel to the epitaxial interface.

7. The semiconductor device according to claim 5,
wherein the body region vertically separates the source region and the current collecting region.

8. The semiconductor device according to claim 7, further comprising:
a trench gate structure extending from a top surface of the transistor layer into the transistor layer, wherein the source region, the body region and the current collecting region are in direct contact with a sidewall of the trench gate structure.

9. The semiconductor device according to claim 8,
wherein the current collecting region and the current propagation region are in direct contact with each other along a second section of the epitaxial interface, and wherein a vertical dopant profile through the second section of the epitaxial interface shows a step at the epitaxial interface.

10. The semiconductor device according to claim 8,
wherein the trench gate structure ends in the transistor layer and wherein an auxiliary region of the second conductivity type extends from a bottom of the trench gate structure to the shielding structure.

11. The semiconductor device according to claim 1,
wherein the current propagation region vertically extends through a gap in the shielding structure, wherein the gap has a vertical extension v0 and a horizontal width w0, and wherein an aspect ratio v0/w0 of the gap in the shielding structure is at least 0.3, for example at least 1 or at least 5.

12. The semiconductor device according to claim 1, further comprising:
a depletable first pillar region of the first conductivity type and depletable second pillar regions of the second conductivity, wherein the first pillar region is formed in the foundation layer in direct contact with the current propagation region, and wherein the second pillar regions are formed in the foundation layer in direct contact with the shielding structure.

13. The semiconductor device according to claim 1,
wherein the current propagation region comprises a central portion in the gap in the shielding structure, and a heavily doped sidewall portion between the central portion and the shielding structure.

14. A method of manufacturing a semiconductor device, the method comprising:
forming a foundation layer based on single-crystalline silicon carbide, the foundation layer comprising a non-depletable shielding structure of a second conductivity type, and a current propagation region of a first conductivity type extending from a foundation layer surface of the foundation layer through a gap in the shielding structure; and
forming a transistor layer on the foundation layer surface, the transistor layer comprising a transistor cell (TC) configured to control a current through the current propagation region, wherein along a vertical line orthogonal to an epitaxial interface between the transistor layer and the foundation layer and through a pn junction between the shielding structure and a region of the first conductivity type in the transistor layer, a net dopant concentration changes by at least 1e17 1/cm³ per 0.1 μm at the position of the pn junction.

15. The method according to claim 14,
wherein forming the transistor layer comprises growing the transistor layer on the foundation layer surface by epitaxy after forming the shielding structure in the foundation layer.

16. The method according to claim 14,
wherein forming the foundation layer (200) comprises forming depletable first pillar regions (241) of the first conductivity type and depletable second pillar regions (242) of the second conductivity in the foundation layer (200) before forming the shielding structure (260), wherein the shielding structure (260) is formed between the epitaxial interface (201) and the first and second pillar regions (241, 242).

17. The method according to claim 14,
wherein forming the transistor layer comprises forming a gate trench extending from a main surface of the transistor layer into the transistor layer, implanting dopants of the first conductivity type through a bottom of the gate trench to form an auxiliary region between the gate trench and the shielding structure, and forming a trench gate structure in the gate trench.

18. The method according to claim 14,
wherein forming the foundation layer comprises forming, before forming the transistor layer, a channel trench in the gap of the shielding structure and filling the channel trench with doped semiconductor material to form at least a portion of the current propagation region.

19. The method according to claim 18, further comprising:
implanting dopant atoms in sidewalls of the channel trench before filling the channel trench.

20. A semiconductor device, comprising:
a foundation layer based on single-crystalline silicon carbide and comprising a current propagation region of a first conductivity type and a non-depletable shielding structure of a second conductivity type; and
a transistor layer based on epitaxially grown single-crystalline silicon carbide and comprising a transistor cell (TC) configured to control a current through the current propagation region,
wherein an epitaxial interface is between the foundation layer and the transistor layer;
wherein the current propagation region extends at least one of from the epitaxial interface or between neighboring partial regions of the shielding structure; and
wherein along a vertical line orthogonal to the epitaxial interface and through a pn junction between the shielding structure and a region of the first conductivity type in the transistor layer, a net dopant concentration changes at the position of the pn junction.
